(19) United States
(12) Patent Application Publication
(10) Pub. No.: US 2010/0327453 A1
(43) Pub. Date: Dec. 30, 2010

(54) Semiconductor Device and Method of Manufacturing the Same

(75) Inventor: Hyun Sub Kim, Yeoju-Gun (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/787,880

(22) Filed: May 26, 2010

(30) Foreign Application Priority Data
Jun. 29, 2009 (KR) 10-2009-0058454

(51) Int. Cl. H01L 23/522; H01L 21/50

(52) U.S. Cl. 257/773; 438/107; 257/E23.145; 257/E21.499

(57) ABSTRACT

A semiconductor device comprises a first substrate in which a first memory cell array is formed, a second substrate in which a second memory cell array, a page buffer, and decoders are formed, and a coupling structure formed on the first and second substrates and configured to have the page buffer and the decoders operated in conjunction with the first and second memory cell arrays. The second substrate is adhered over the first substrate.

### CROSS-REFERENCE TO RELATED APPLICATION

Priority to Korean patent application number 10-2009-0058454 filed on Jun. 29, 2009, the entire disclosure of which is incorporated by reference herein, is claimed.

### BACKGROUND

Exemplary embodiments relate to a semiconductor device and a method of manufacturing the same and, more particularly, to a semiconductor device and a method of manufacturing the same, which are capable of improving the memory capacity.

A semiconductor device includes a memory cell array area and a peripheral area. In the memory cell array area are formed a number of memory cells for storing data. In the peripheral area are formed a number of circuit elements for generating biases for the program, erase, and read operations of the memory cells and for outputting them.

In general, the memory cells constituting the cell array area and the circuit elements constituting the peripheral area are formed on the same semiconductor substrate. To increase the memory capacity of the semiconductor device, a new process technique for reducing the size of elements is being introduced. Although the new process technique is introduced, however, there is a limit in reducing the size of the elements. Accordingly, there is a need for a semiconductor device and a method of manufacturing the same, which are capable of improving the memory capacity even though the size of elements is not reduced.

### BRIEF SUMMARY

Exemplary embodiments relate to a semiconductor device and a method of manufacturing the same, which are capable of improving the memory capacity.

A semiconductor device according to an aspect of this disclosure comprises a first substrate in which a first memory cell array is formed; a second substrate in which a second memory cell array, a page buffer, and decoders are formed; and a coupling structure formed on the first and second substrates, and configured to have the page buffer and the decoders operated in conjunction with the first and second memory cell arrays. The second substrate is adhered over the first substrate.

The coupling structure comprises a first contact plug coupled to a first junction of the first substrate and a second junction of the second substrate; a second contact plug coupled to the page buffer; and a bit line coupled to the first and second contact plugs, wherein the first junction is formed in the first substrate between first drain select lines of the first memory cell array and the second junction is formed in the second substrate between second drain select lines of the second memory cell array.

The decoders comprise a first decoder operated in conjunction with the first memory cell array and a second decoder operated in conjunction with the second memory cell array.

The coupling structure comprises a third contact plug coupled to a first word line of the first memory cell array; a fourth contact plug coupled to a second word line of the second memory cell array; a fifth contact plug coupled to the first decoder; a sixth contact plug coupled to the second decoder; a first signal line coupled to the third and fifth contact plugs; and a second signal line coupled to the fourth and sixth contact plugs.

The first and second decoders face each other with the second memory cell array interposed between the first and second decoders.

A method of manufacturing a semiconductor device according to another aspect of this disclosure comprises forming a first memory cell array over a first substrate; adhering a second substrate on the first memory cell array; forming a second memory cell array, a page buffer, and decoders over the second substrate; and forming a coupling structure on the first and second substrates so that the page buffer and the decoders can be operated in conjunction with the first and second memory cell arrays.

In accordance with the method, the forming of a first memory cell array over a first substrate comprises forming first drain select lines, first source select lines, and first word lines disposed between the first drain select lines and the first source select line over the first substrate and forming a first junction in the first substrate between the first drain select lines.

In accordance with the method, the forming of a second memory cell array, a page buffer, and decoders over the second substrate comprises forming second drain select lines, second source select lines, and second word lines disposed between the second drain select lines and the second source select lines over the second substrate and forming a second junction in the second substrate between the second drain select lines.

The coupling structure comprises a first contact plug coupled to the first and second junctions; a second contact plug coupled to the page buffer; and a bit line coupled to the first and second contact plugs.

The decoders comprise a first decoder operated in conjunction with the first memory cell array and a second decoder operated in conjunction with the second memory cell array. The coupling structure comprises a third contact plug coupled to the first word line; a fourth contact plug coupled to the second word line; a fifth contact plug coupled to the first decoder; a sixth contact plug coupled to the second decoder; a first signal line coupled to the third and fifth contact plugs; and a second signal line coupled to the fourth and sixth contact plugs. The first and second decoders face each other with the second memory cell array interposed between the first and second decoders.

The method further comprises implanting hydrogen ions into the second substrate, before adhering the second substrate. The method further comprises removing part of the second substrate to a depth where the hydrogen ions have been implanted so that the second substrate is made thin, before forming the second memory cell array, the page buffer, and the decoders.

### BRIEF DESCRIPTION OF THE DRAWINGS

FIG. 1 is a diagram of a semiconductor device according to this disclosure;

FIGS. 2A to 2H are cross-sectional views of the semiconductor device taken along line A-A′ shown in FIG. 1, which is parallel to bit lines BL; and

FIGS. 3A to 3G are cross-sectional views of the semiconductor device taken along line B-B shown in FIG. 1, which is parallel to word lines WL.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

FIG. 1 is a diagram of a semiconductor device according to this disclosure.

Referring to FIG. 1, the semiconductor device according to this disclosure includes a peripheral area and a number of memory cell array areas 110. The memory cell array areas 110 are formed and stacked on different layers. The peripheral area is formed on the same layer as the highest one of the memory cell array areas 110.

Each of the memory cell array areas 110 is an area in which a number of memory cells for storing data are formed. The peripheral area is an area in which a number of circuit elements for generating biases for the program, erase, and read operations of not only the memory cells formed on the same layer as the peripheral area, but also the memory cells formed on different layers from the peripheral area and for outputting them are formed.

In the memory cell array area 110 is formed a memory cell array, including a number of word lines WL and the memory cells coupled to the word lines WL. The memory cell array is classified into a first memory cell array and a second memory cell array. The first memory cell array and the second memory cell array have a stack structure. Meanwhile, the word lines WL include first word lines WLb, constituting the first memory cell array, and second word lines WLt, constituting the second memory cell array. A number of bit lines BL are formed over the second word lines WLt and arranged to cross the second word lines WLt.

In the peripheral area are formed the circuit elements, including a page buffer unit 120, a first row decoder unit 140, and a second row decoder unit 130.

The page buffer unit 120 is coupled to the first and second memory cell arrays of the memory cell array area 110 through the bit lines BL and configured to store data in the memory cells or read data stored in the memory cells. The page buffer unit 120 includes a number of page buffers corresponding to the respective bit lines BL.

The second row decoder unit 130 is configured to select the second word line WLt, coupled to a memory cell to be programmed, in response to a row address signal and to supply corresponding word line voltages to the selected second word line WLt and the remaining second word lines.

The first row decoder unit 140 is configured to select the first word line WLb, coupled to a memory cell to be programmed, in response to a row address signal and to supply corresponding word line voltages to the selected first word line WLb and the remaining first word lines.

The above-described semiconductor device according to this disclosure can improve the memory capacity because a number of the memory cell arrays are stacked. Furthermore, as described above, the peripheral area is formed on the same layer as the highest one of the memory cell array areas. Accordingly, stress applied to the circuit elements of the peripheral area during a process of manufacturing the semiconductor device can be minimized.

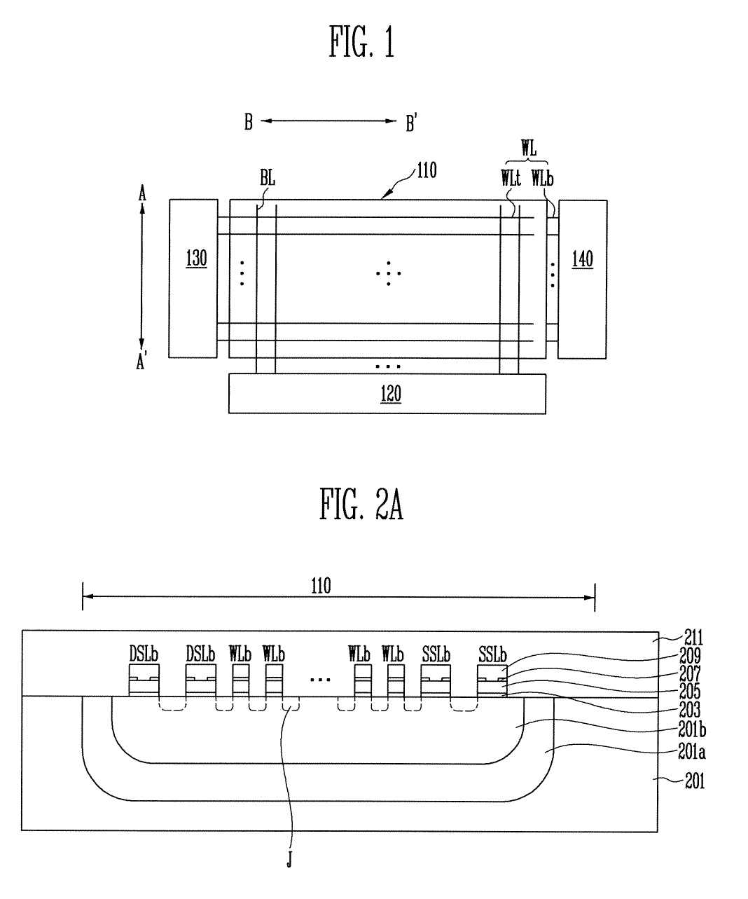

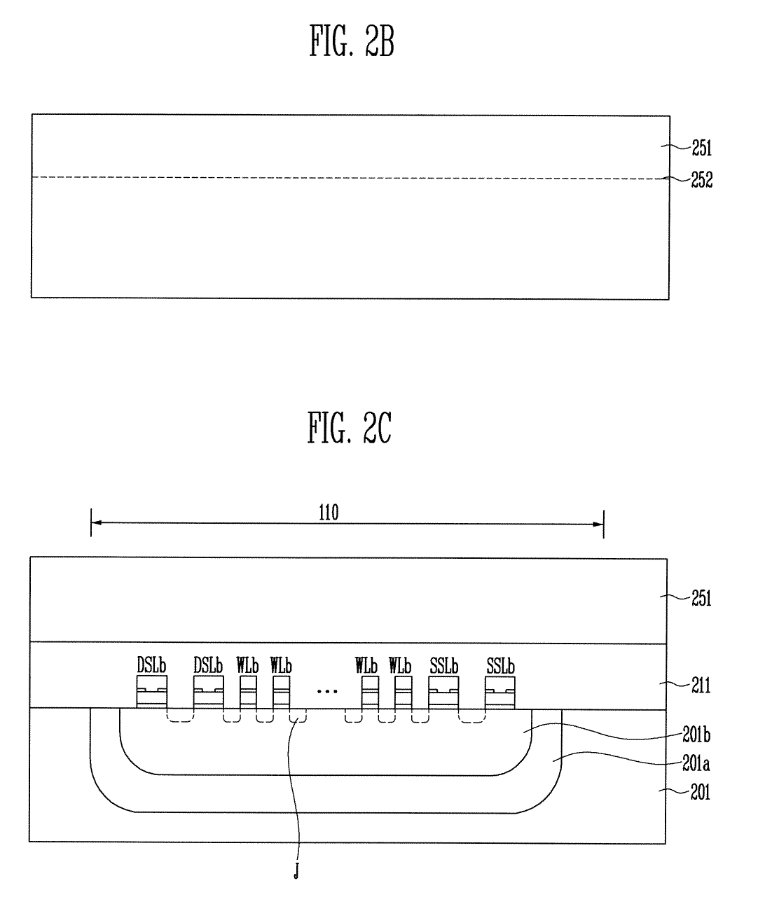

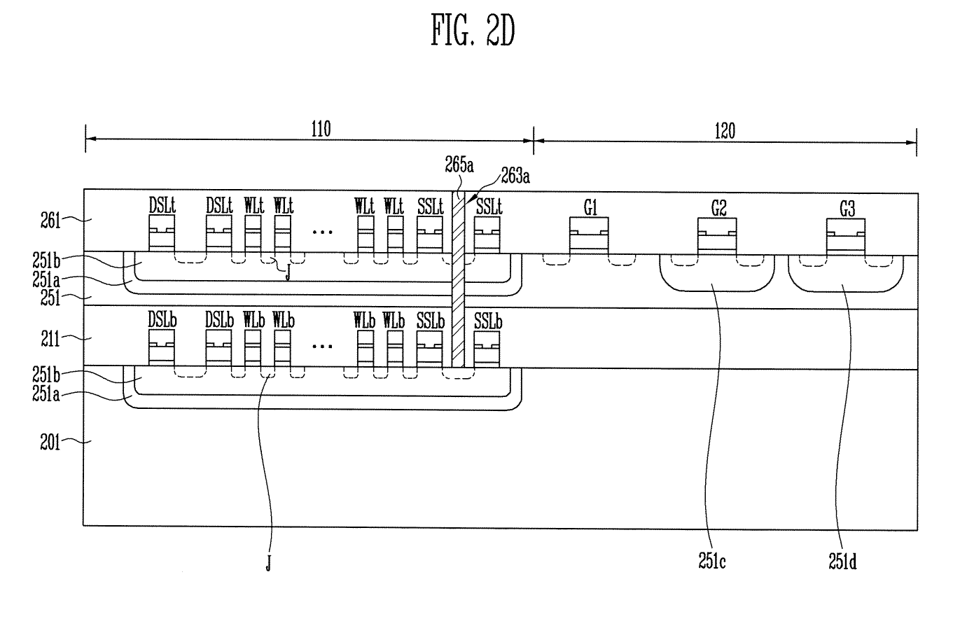

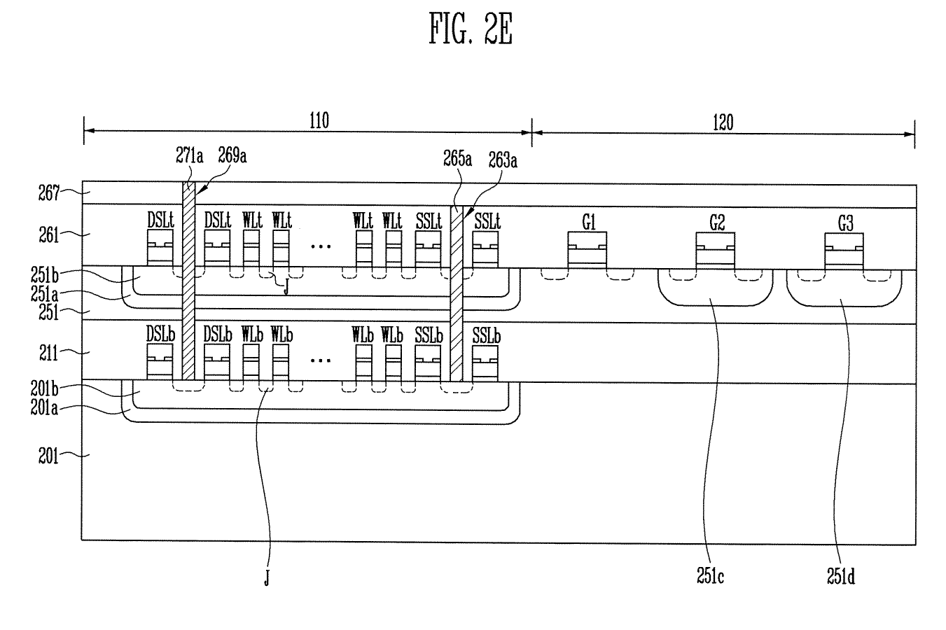

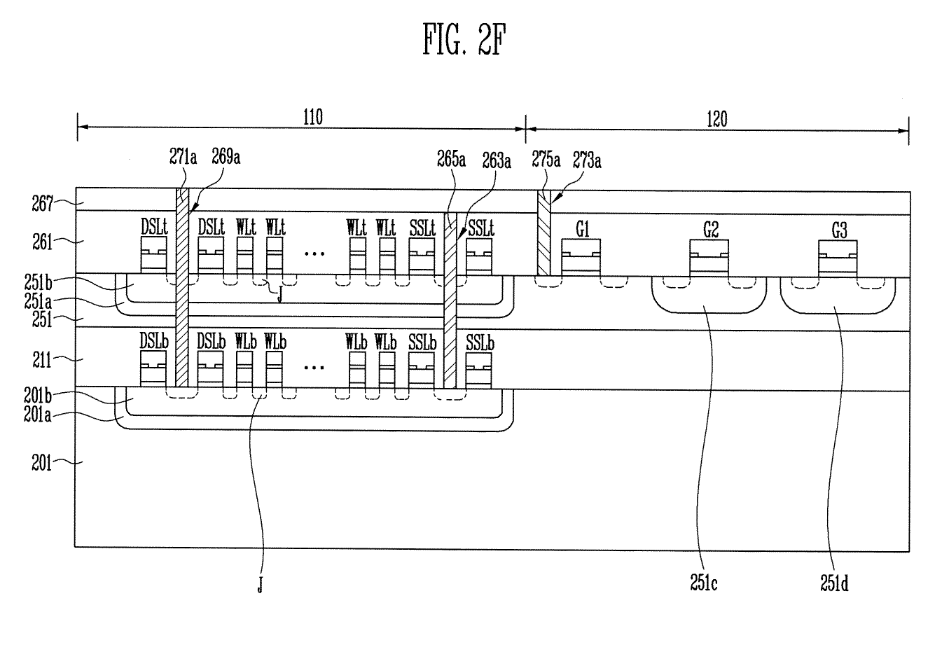

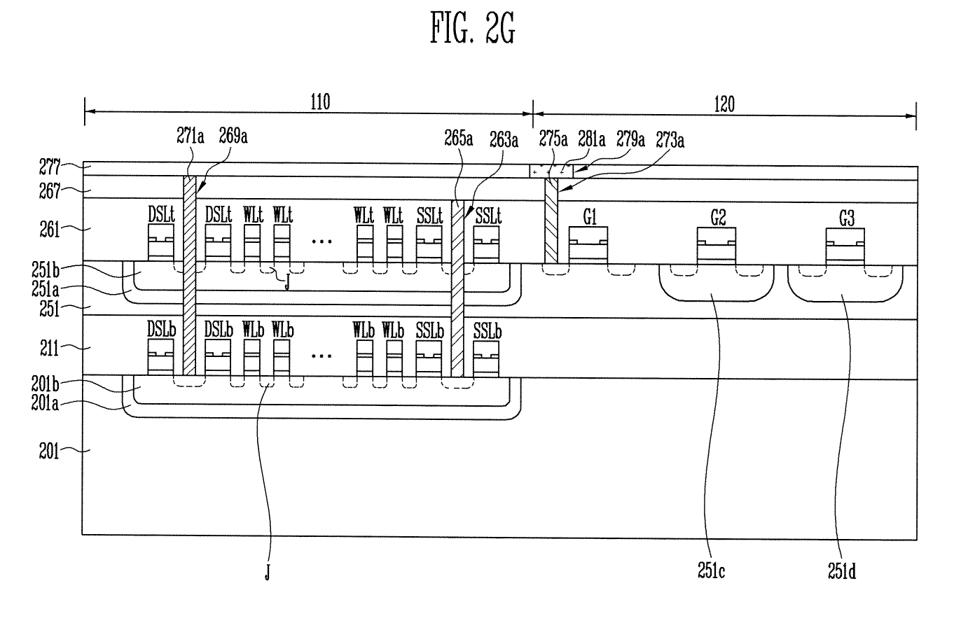

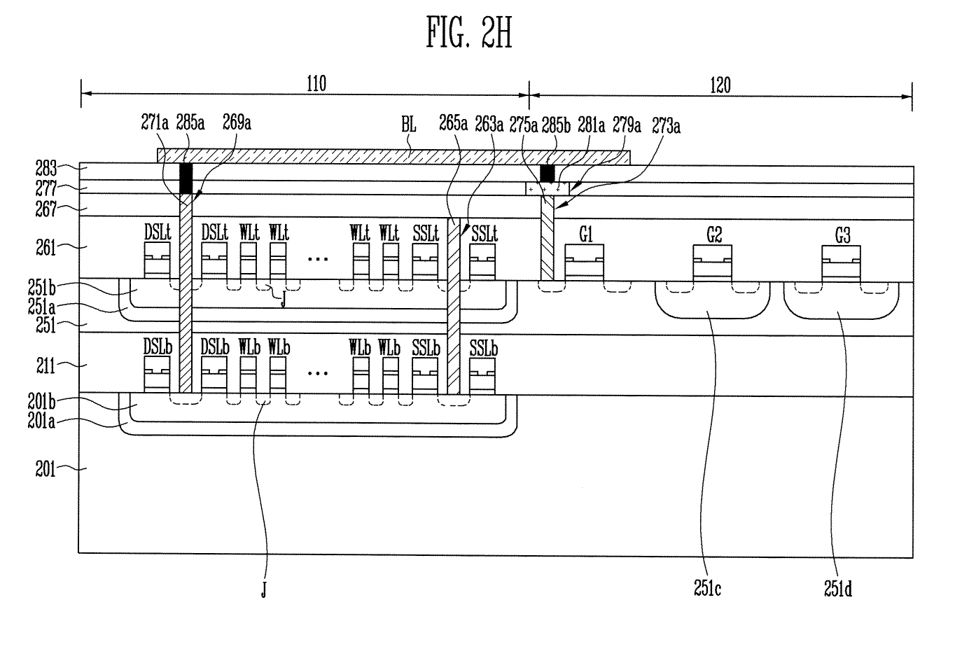

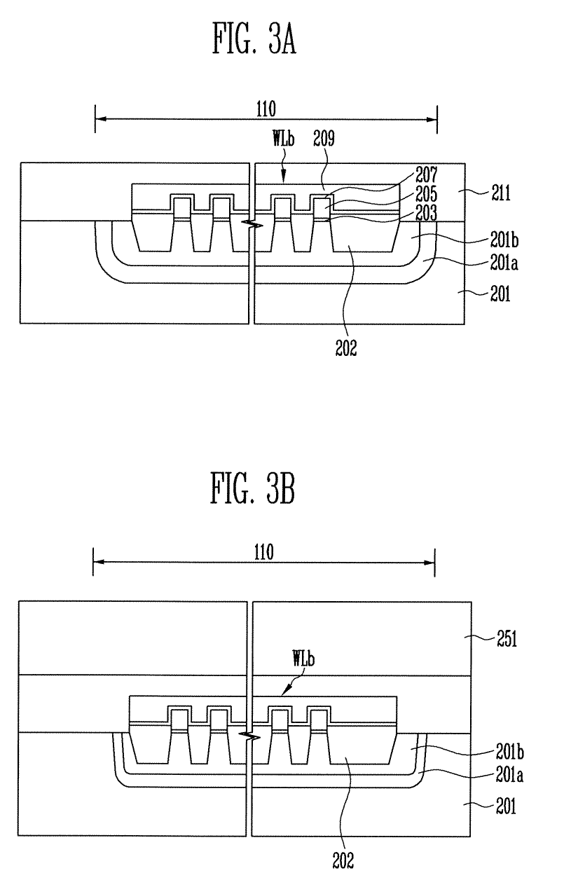

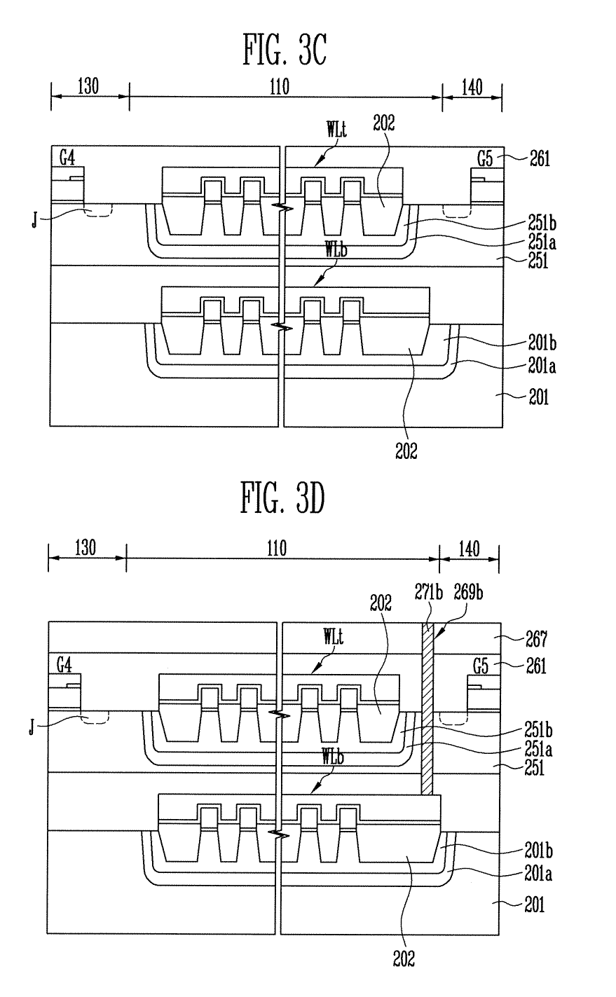

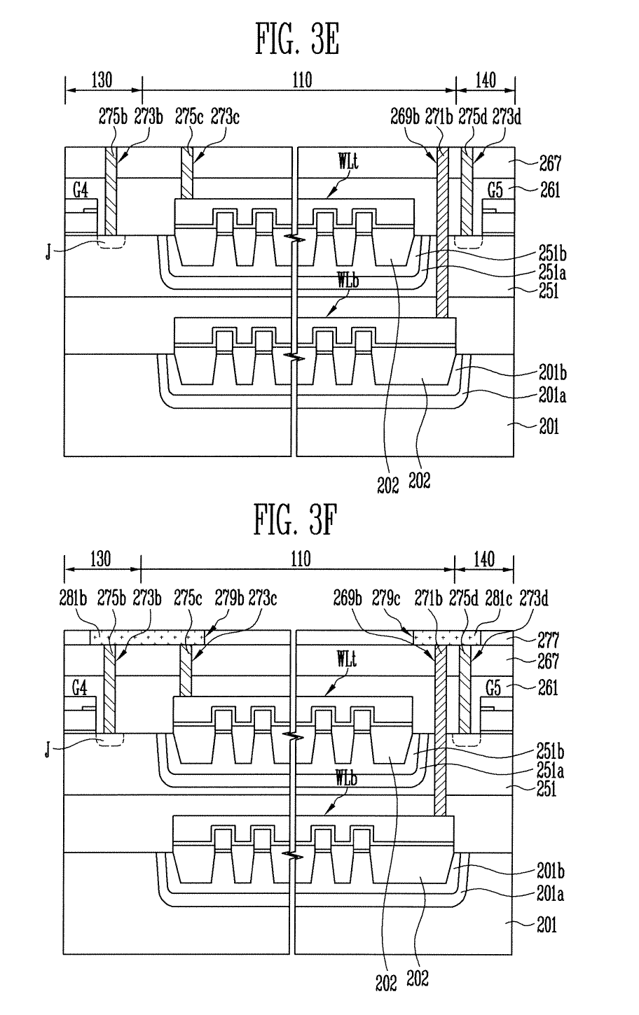

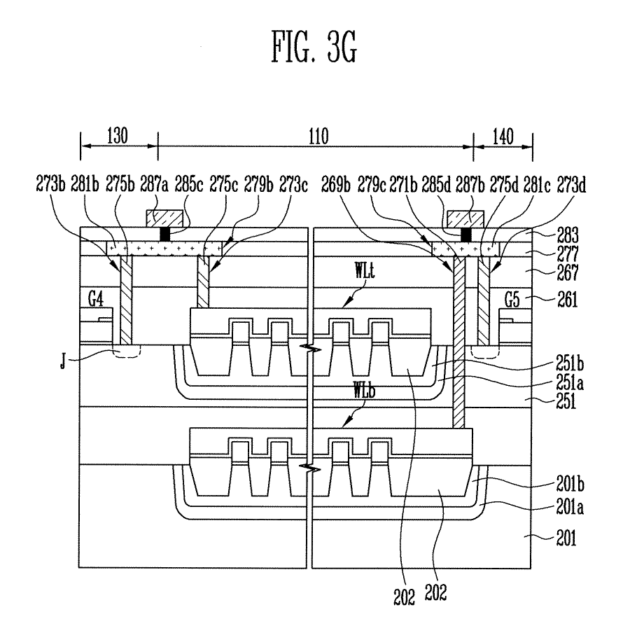

A method of manufacturing the semiconductor device according to this disclosure is described in detail below with reference to FIGS. 2A to 3G. Hereinafter, the method of manufacturing the semiconductor device is described in detail by taking an NAND flash memory device as an example.

FIGS. 2A to 2H are cross-sectional views of the semiconductor device taken along line A-A′ shown in FIG. 1, which is parallel to bit lines BL. FIGS. 3A to 3G are cross-sectional views of the semiconductor device taken along line B-B′ shown in FIG. 1, which is parallel to word lines WL.

Referring to FIGS. 2A and 3A, first, first gate patterns, including a number of the first word lines WLb, a number of first drain select lines DSLb, and a number of first source select lines SSLb, are formed over a first substrate 201 including at least one bulk structure of an N well and a P well. The first word lines WLb are formed between a neighboring first drain select line DSLb and a neighboring first source select lines SSLb.

For example, in the case in which the first substrate 201 is a P type semiconductor substrate, a bulk structure, including a triple N (TN) well 201a and a P well 201b formed within the TN well 201a, is formed in the first substrate 201. The first gate patterns are formed over the P well 201b of the first substrate 201, having the bulk structure, with gate insulating layers 203 interposed between the respective first gate patterns and the P well 201b.

An example of a method of forming the first gate patterns is described in detail below. First, the gate insulating layer 203 and a first conductive layer 205 are formed over the first substrate 201, including the TN well 201a and the P well 201b. The gate insulating layer 203 can be formed of an oxide layer and can be formed through an oxidization process. The gate insulating layer 203 formed through the oxidization process can be formed of a silicon oxide (SiO₂) layer. The first conductive layer 205 is used as a floating gate for storing electric charges and can be formed of a polysilicon layer.

Next, a number of trenches are formed in the P well 201b by etching the first conductive layer 205, the gate insulating layer 203, and the first substrate 201. The inside of the trenches is filled with insulating material, thereby forming isolation layers 202 in the respective trenches. The trenches can be formed by forming isolation hard mask patterns over the first conductive layer 205 and using the isolation hard mask patterns as etch barriers. The isolation hard mask patterns can be removed after the isolation layers 202 are formed. The isolation layers 202 preferably have a top surface lower than the first conductive layer 205, but higher than the gate insulating layer 203. Here, areas of the first substrate 201 in which the isolation layers 202 are not formed are defined as active areas. Through the above process, the gate insulating layer 203 and the first conductive layer 205 remain only over each of the active areas of the P well 201b.

A dielectric layer 207 is formed on a surface of the first conductive layer 205. Here, the dielectric layer 207 of areas in which the first drain select line DSLb and the first source select lines SSLb will be formed includes a hole (not shown) through which the first conductive layer 205 is exposed. The first conductive layer 205 can be electrically coupled to the second conductive layer 209 through the hole formed in the dielectric layer 207. Meanwhile, the dielectric layer 207 can have a stack structure, including oxide/nitride/oxide (ONO) layers.

The second conductive layer 209 is formed over the dielectric layer 207. The second conductive layer 209 is used as a control gate. The second conductive layer 209 can be formed of a polysilicon layer, a stack layer of the polysilicon layer and a metal silicide layer, or a stack layer of the polysilicon layer and a metal layer. After the gate hard mask patterns (not shown) are formed over the second conductive layer 209, the second conductive layer 209, the dielectric layer 207, and the first conductive layer 203 are etched to expose the gate insulating layer 203 or the first substrate 201 using the gate hard mask patterns as etch barriers. Accordingly, the first gate patterns, including a number of the first word lines WLb, a number of the first drain select line DSLb, and a number of the first source select lines SSLb over the P well 201b. The gate hard mask patterns are formed in parallel in a direction to cross the active areas and the isolation layers 202. Thus, the first conductive layer 203 is separated into a number of patterns over the active areas. The first gate patterns defined by the patterning of the second conductive layer 209 are formed in such a way as to cross the isolation layers 202.

After the first gate patterns, including the first word lines WLb, the first drain select lines DSLb, and the first source select lines SSLb, are formed as described above, impurity ions are implanted using the first gate patterns as a mask, thereby forming junctions J (refer to FIGS. 2C and 3C) in the first substrate 201 between the first gate patterns.

After the junctions J are formed, a first interlayer dielectric layer 211 is formed over the first substrate 201 so that the first word lines WLb, the first drain select lines DSLb, and the first source select lines SSLb are covered. Next, a surface of the first interlayer dielectric layer 211 is polished using a chemical mechanical polishing (CMP) process.

Referring to FIG. 2B, there is prepared a second substrate 251 to be adhered to the top surface of the first interlayer dielectric layer 211. Before the second substrate 251 is adhered to the top surface of the first interlayer dielectric layer 211, a boundary portion 252 is formed by implanting hydrogen (H) ions into the second substrate 251 using a specific depth of the second substrate 251 as a target. The bonding strength of the second substrate 251 is weak in the portion into which the H ions are implanted as described above. Accordingly, since the portion of the second substrate 251 into which the hydrogen ions are implanted can be easily etched, the second substrate 251 can be easily made thin.

Referring to FIGS. 2C and 3B, the second substrate 251 is adhered to the top surface of the first interlayer dielectric layer 211. When the second substrate 251 is adhered, the surface of the second substrate 251 into which the hydrogen ions are implanted should be adhered to the top surface of the first interlayer dielectric layer 211. Next, the second substrate 251 is made thin by removing the portion of the second substrate 251 into which the hydrogen ions are implanted using a process, such as CMP. Here, since the hydrogen ions have been implanted into the boundary portion (refer to 252 of FIG. 2B) of the second substrate 251 and so the bonding strength of the second substrate 251 has been lowered, the second substrate 251 can be easily made thin.

Referring to FIGS. 2D and 3C, the bulk structure, including at least one of an N well and a P well, is formed in the second substrate 251. For example, if the second substrate 251 is a P type semiconductor substrate, the bulk structure, including a TN well 251a and a P well 251b formed within the TN well 251a, is formed in the first substrate 201 in the memory cell array area 110. A P well 251c or an N well 251d is formed in the peripheral area depending on the type of the circuit elements 120, 130, and 140. More particularly, a number of NMOS transistors and a number of PMOS transistors are formed in the peripheral area, including the circuit elements 120, 130, and 140. The P well 251c is formed in a portion of the peripheral area in which the NMOS transistor will be formed, and the N well 251d is formed in a portion of the peripheral area in which the PMOS transistor will be formed.

Next, second gate patterns, including a number of the second word lines WLt, a number of second drain select lines DSLt, a number of second source select lines SSLt, and a number of driving gates G1, G2, G3, G4, and G5, are formed over the second substrate 251 including the bulk structure. The second word lines WLt are formed between a neighboring second drain select line DSLt and a neighboring second source select lines SSLt.

The second gate patterns further includes the driving gates G1, G2, G3, G4, and G5, constituting the circuit elements, as compared with the first gate patterns described above with reference to FIGS. 2A and 3A. The second gate patterns are manufactured using the same method as the first gate patterns. Meanwhile, a first conductive layer and a second conductive layer, constituting the driving gates G1, G2, G3, G4, and G5 of the second gate patterns, can be electrically coupled together through holes formed in a dielectric layer like the second drain select lines DSLt and the second source select lines SSLt.

The second word lines WLt and the first word lines WLb are formed to overlap with each other in parallel. The second drain select lines DSLt and the first drain select lines DSLb are formed to overlap with each other in parallel. Furthermore, the second source select lines SSLt and the first source select lines SSLb are formed to overlap with each other in parallel.

The second word lines WLt, the second drain select lines DSLt, and the second source select lines SSLt are formed in the memory cell array area 110 of the second substrate 251. The driving gates G1, G2, G3, G4, and G5 are formed in the peripheral area of the second substrate 251, including the page buffer unit 120, the second row decoder unit 130, and the first row decoder unit 140.

The second row decoder unit 130 and the first row decoder unit 140 are formed at the end of the word line WLb or WLt and preferably are formed to face each other with the memory cell array area 110 interposed therebetween. The page buffer unit 120 preferably is formed at the end of the bit line subsequently formed to cross the word line WLb or WLt.

After the second gate patterns, including the second word lines WLt, the second drain select lines DSLt, the second source select lines SSLt, and the driving gates G1, G2, G3, G4, and G5, are formed as described above, impurity ions are implanted into the second substrate 251 using the second gate patterns as a mask, thereby forming junctions J in the second substrate 251. The process of forming the junctions J in the second substrate 251 can be divided into a process of forming the junctions J in the memory cell array area 110 and a process of forming the junctions J in the peripheral area, including the circuit elements 120, 130, and 140. In particular, the process of forming the junctions J in the peripheral area, including the circuit elements 120, 130, and 140 can be divided into a process of forming the junctions in NMOS transistors and a process of forming the junctions in PMOS transistors. In the case in which, as described above, the junctions J are formed in each area, a photoresist pattern can be used as a mask.

After the junctions J are formed in the second substrate 251, a second interlayer dielectric layer 261 is formed over the second substrate 251 so that the second word lines WLt, the second drain select lines DSLt, the second source select lines SSLt, and the driving gates G1, G2, G3, G4, and G5 are covered. A surface of the second interlayer dielectric layer 261 is polished using a CMP process.

A first contact hole 263a is formed by etching the second interlayer dielectric layer 261, the junction J, and the second substrate 251 between the second source select lines SSLt and the first interlayer dielectric layer 211 between the first source select lines SSLb. A first contact plug 265a is formed within the first contact hole 263a.

The first contact hole 263a is formed to expose the junction J between the second source select lines SSLt and also the junction J between the first source select lines SSLb. The first contact hole 263a can be formed through an etch process using a photoresist pattern, formed by a photolithography process, as an etch barrier.

To facilitate the operation of the elements, a surface of the second substrate 251, exposed after the first contact hole 263a is formed, can be further doped with impurity ions (e.g., n type impurity ions) of the same kind as the impurity ions implanted into the junctions formed in the memory cell array area 110.

The first contact plug 265a can be formed by depositing a conductive material to a thickness enough to fill the inside of the first contact hole 263a and polishing a surface of the conductive material using a polishing process, such as CMP, so that the second interlayer dielectric layer 261 is exposed. The first contact plug 265a is coupled to the junction J between the second source select lines SSLt and to the junctions J between the first source select lines SSLb.

In some embodiments, to facilitate the operation of the elements, the first contact plug 265a can be formed using polysilicon doped with impurity ions (e.g., n type impurity ions) of the same kind as the impurity ions implanted into the junctions formed in the memory cell array area 110.

Referring to FIGS. 2E and 3D, a third interlayer dielectric layer 267 is formed over the second interlayer dielectric layer 261 so that the first contact plug 265a is covered.

A second contact hole 269a is formed by etching the third interlayer dielectric layer 267, the second interlayer dielectric layer 261, the junction J, and the second substrate 251 between the second drain select lines DSLt and the first interlayer dielectric layer 211 between the first drain select lines DSLb. A second contact plug 271a is formed within the second contact hole 269a.

The second contact hole 269a is formed to expose the junction J between the second drain select lines DSLt and also the junction J between the first drain select lines DSLb. The second contact hole 269a can be formed through an etch process using a photoresist pattern, formed by a photolithography process, as an etch barrier.

In some embodiments, to facilitate of the operation of the elements, a surface of the second substrate 251, exposed after the second contact hole 269a is formed, can be further doped with impurity ions (e.g., n type impurity ions) of the same kind as the impurity ions implanted into the junctions formed in the memory cell array area 110.

The second contact plug 271a can be formed by depositing a conductive material of a thickness enough to fill the inside of the second contact hole 269a and polishing a surface of the conductive material using a polishing process, such as CMP, so that the third interlayer dielectric layer 267 is exposed. The second contact plug 271a is coupled to the junction J between the second drain select lines DSLt and also the junction J between the first drain select lines DSLb.

In some embodiments, to facilitate of the operation of the elements, the second contact plug 271a can be formed using polysilicon doped with impurity ions (e.g., n type impurity ions) of the same kind as the impurity ions implanted into the junctions formed in the memory cell array area 110.

When the second contact hole 269a is formed, a third contact hole 269b through which one end of the first word line WLb is exposed can be formed simultaneously with the second contact hole 269a. The one end of the first word line WLb exposed through the third contact hole 269b is adjacent to the first row decoder 140.

When the second contact plug 271a is formed, a third contact plug 271b can be formed simultaneously with the second contact plug 271a. The third contact plug 271b is formed to fill the inside of the third contact hole 269b and coupled to one end of the first word line WLb. The one end of the first word line WLb coupled to the third contact plug 271b is adjacent to the first row decoder 140.

Referring to FIGS. 2F and 3E, a fourth contact hole 273c is formed by etching the second and third interlayer dielectric layers 261, 267 formed over one end of the second word line WLt adjacent to the second row decoder 130. A fourth contact plug 275c is formed within the fourth contact hole 273c.

The fourth contact hole 273c is formed to expose the one end of the second word line WLt adjacent to the second row decoder 130. The fourth contact hole 273c can be formed through an etch process using a photoresist pattern, formed by a photolithography process, as an etch barrier.

The fourth contact plug 275c can be formed by depositing a conductive material of a thickness enough to fill the inside of the fourth contact hole 273c and polishing a surface of the conductive material using a polishing process, such as CMP, so that the third interlayer dielectric layer 267 is exposed. The fourth contact plug 275c is coupled to one end of the second word line WLt adjacent to the second row decoder 130.

Meanwhile, when the fourth contact hole 273c is formed, fifth to seventh contact holes 273a, 273b, and 273d can be formed simultaneously with the fourth contact hole 273c. The junctions J formed on one ends of the first to third driving gates G1, G4, and G5, from among the second gate patterns of the peripheral area of the circuit elements 120, 130, and 140, are respectively exposed through the fifth to seventh contact holes 273a, 273b, and 273d.

The fifth contact hole 273a is formed to expose the junction J formed on one side of the first gate pattern G1 included in the page buffer unit 120. Here, the first driving gate G1 can be a pattern to which a bit line selection signal or a discharge signal is supplied when the semiconductor device is driven. The memory cell array is coupled to a page buffer in response to the bit line selection signal, and voltage is supplied to the memory cell array, coupled to the bit lines, in response to the discharge signal.

The sixth contact hole 273b is formed to expose the junction J formed on one side of the second driving gate G4 included in the first row decoder 140. The second driving gate G4 can be a pattern to which a block selection signal is supplied when the semiconductor device is driven. The block selection signal supplied to the second driving gate G4 is supplied in order to select one of a number of first memory cell blocks formed on the first substrate 201.

The seventh contact hole 273d is formed to expose the junction J formed on one side of the third driving gate G5 included in the second row decoder 130. The third driving gate G5 can be a pattern to which the block selection signal is supplied when the semiconductor device is driven. The block selection signal supplied to the third driving gate G5 is used to select one of a number of second memory cell blocks formed on the second substrate 251.

A word line voltage is supplied to the first and second word lines WLb and WLt of a memory cell block selected in response to the block selection signal.

When the fourth contact plug 275c is formed, fifth to seventh contact plugs 275a, 275b, and 275d can be formed simultaneously with the fourth contact plug 275c. The fifth contact plug 275a is formed to fill the inside of the fifth contact hole 273a and coupled to the junction J formed on one side of the first driving gate G1. The sixth contact plug 275b is formed to fill the inside of the sixth contact hole 273b and coupled to the junction J formed on one side of the second driving gate G4. The seventh contact plug 275d is formed to fill the inside of the seventh contact hole 273d and coupled to the junction J formed on one side of the third driving gate G5.

Referring to FIGS. 2G and 3F, a fourth interlayer dielectric layer 277 is formed over the third interlayer dielectric layer 267 so that the second to seventh contact plugs 271a, 271b, 275c, 275a, 275b, and 275d are covered.

The fourth interlayer dielectric layer 277 formed over the fifth contact plug 275a is etched to form a first pad hole 279a. A first pad 281a is formed within the first pad hole 279a.

The first pad hole 279a has a width wider than the fifth contact plug 275a and exposes the fifth contact plug 275a. The first pad hole 279a can be formed through an etch process using a photoresist pattern formed by a photolithography process, as an etch barrier.

The first pad 281a can be formed by depositing a conductive material of a thickness enough to fill the inside of the first pad hole 279a and polishing a surface of the conductive material using a polishing process, such as CMP, so that the fourth interlayer dielectric layer 277 is exposed. The first pad 281a is formed to have a width wider than the fifth contact plug 275a and coupled to the fifth contact plug 275a.

Meanwhile, when the first pad hole 279a is formed, second and third pad holes 279b, 279c can be formed simultaneously with the first pad hole 279a. A single second pad hole 279b exposes the fourth contact plug 275c and the sixth contact plug 275b. A single third pad hole 279c exposes the third contact plug 271b and the seventh contact plug 275d.

When the first pad 281a is formed, second and third pads 281b, 281c can be formed simultaneously with the first pad 281a. The second pad 281b is formed to fill the inside of the second pad hole 279b and coupled to the fourth contact plug 275c and the sixth contact plug 275b. The third pad 281c is formed to fill the inside of the third pad hole 279c and coupled to the third contact plug 271b and the seventh contact plug 275d.

Referring to FIGS. 2H and 3G, a fifth interlayer dielectric layer 283 is formed over the fourth interlayer dielectric layer 277 so that the first to third pad 281a, 281b, and 281c are covered.

The fourth and fifth interlayer dielectric layers 277, 283 formed over the second contact plug 271a are etched to form an eighth contact hole through which the second contact plug 271a is exposed. An eighth contact plug 285a coupled to the second contact plug 271a is formed within the eighth contact hole.

The eighth contact hole can be formed through an etch process using a photoresist pattern, formed by a photolithography process, as an etch barrier. The eighth contact plug 285a can be formed by depositing a conductive material and polishing a surface of the conductive material using a polishing process, such as CMP, so that the fifth interlayer dielectric layer 283 is exposed.

Meanwhile, when the eighth contact hole is formed, a ninth contact hole through which the first pad 281a is exposed, a tenth contact hole through which the second pad 218b is exposed, and an eleventh contact hole through which the third pad 281c is exposed are formed simultaneously with the eighth contact hole. Here, the ninth to the eleventh contact hole is formed by etching the fourth interlayer dielectric layer 277. Furthermore, when the eighth contact plug 285a is formed, a ninth contact plug 285b formed to fill the ninth contact hole and coupled to the first pad 281a, a tenth contact plug 285c formed to fill the tenth contact hole and coupled to the second pad 281b, and an eleventh contact plug 285d formed to fill the eleventh contact hole and coupled to the third pad 281c are formed simultaneously with the eighth contact plug 285a.

Next, a conductive layer is deposited and then etched through an etch process using a photoresist pattern, formed by a photolithography process, as an etch barrier, thereby forming the bit line BL and first and second signal lines 287a, 287b.

The bit line BL is coupled to the eighth contact plug 285a and the ninth contact plug 285b. The first signal line 287a is coupled to the tenth contact plug 285c, and the second signal line 287b is coupled to the eleventh contact plug 285d.

Through the above process, the memory cell array area 110 including a number of the memory cell blocks is formed. Each of the memory cell blocks includes a number of the string structures. Each of the string structures includes a source select transistor, a drain select transistor, and a number of memory cells coupled in series between the source select transistor and the drain select transistor. The drain select transistor selectively couples the string structure and the bit line BL together. The source select transistor selectively couples the string structure and a common source line (not shown) coupled to a ground. Memory cells included in different string structures are coupled together through a number of the word lines WLb or WLt. The drain select transistors of the different string structures are coupled together through the drain select lines DSLb or DSLt. The source select transistors the different string structures are coupled together through the source select lines SSLb or SSLt.

In accordance with this disclosure, the second substrate 251 is adhered to the top surface of the first substrate 201 including the string structures, and the string structures are then formed on the second substrate 251. Accordingly, since the string structure including a number of the memory cells for storing data are coupled together in series to form a dual layer, the memory capacity can be double increased.

Furthermore, in this disclosure, the peripheral area including the circuit elements is not formed in the first substrate 201. However, only in the second substrate 251 is formed the peripheral area, including the circuit elements for generating biases for the program, erase, and read operations of the memory cells formed over the first substrate 201 and the second substrate 251 and outputting them. Accordingly, the circuit elements formed in the peripheral area over the second substrate 251 are influenced by heat generated during processes performed over the second substrate 251, but not influenced by heat generated during the time for which the memory cell array is formed on the first substrate 201. This is because the memory cell array is formed on the first substrate 201 and the circuit elements of the peripheral area are then formed. Consequently, thermal stress, applied to the circuit elements of the peripheral area during the time for which the memory cell array is formed, can have the same level as thermal stress applied when a single memory cell array is formed on a single substrate. In other words, in this disclosure, although the memory capacity is improved through the memory cell array of a dual layer, thermal stress applied to the circuit elements can be prevented from increasing.

This disclosure can improve the memory capacity of a device because the memory cell arrays are stacked.

Furthermore, not only the memory cell array formed in the highest layer, but also the memory cell array formed in the underlying layer can be operated through the circuit elements of the peripheral area which is formed on the same plane as the memory cell array formed in the highest layer. Here, the memory cell array and the circuit elements formed in the highest layer are formed at the final state. Accordingly, this disclosure can minimize thermal stress applied to the circuit elements during a manufacturing process and so improve malfunction of the circuit elements due to the thermal stress.

What is claimed is:

1. A semiconductor device, comprising:
a first substrate in which a first memory cell array is formed;
a second substrate in which a second memory cell array, a page buffer, and decoders are formed; and
a coupling structure formed on the first and second substrates, and configured to have the page buffer and the decoders operated in conjunction with the first and second memory cell arrays,
wherein the second substrate is adhered over the first substrate.

2. The semiconductor device of claim 1, wherein the coupling structure comprises:
a first contact plug coupled to a first junction of the first substrate and a second junction of the second substrate;
a second contact plug coupled to the page buffer; and
a bit line coupled to the first and second contact plugs,
wherein the first memory cell array includes first drain select lines and the second memory cell array includes second drain select lines and the first junction is formed in the first substrate between the first drain select lines and the second junction is formed in the second substrate between the second drain select lines.

3. The semiconductor device of claim 1, wherein the decoders comprise:
a first decoder operated in conjunction with the first memory cell array; and
a second decoder operated in conjunction with the second memory cell array.

4. The semiconductor device of claim 3, wherein the coupling structure comprises:
a third contact plug coupled to a first word line of the first memory cell array;
a fourth contact plug coupled to a second word line of the second memory cell array;
a fifth contact plug coupled to the first decoder; a sixth contact plug coupled to the second decoder;
a first signal line coupled to the third and fifth contact plugs; and
a second signal line coupled to the fourth and sixth contact plugs.

5. The semiconductor device of claim 3, wherein the first and second decoders face each other with the second memory cell array interposed between the first and second decoders.

6. A method of manufacturing a semiconductor device, the method comprising:
forming a first memory cell array over a first substrate;
adhering a second substrate on the first memory cell array;
forming a second memory cell array, a page buffer, and decoders over the second substrate; and
forming a coupling structure on the first and second substrates so that the page buffer and the decoders can be operated in conjunction with the first and second memory cell arrays.

7. The method of claim 6, wherein forming a first memory cell array over a first substrate comprises:
forming first drain select lines, first source select lines, and first word lines disposed between the first drain select lines and the first source select line over the first substrate; and
forming a first junction in the first substrate between the first drain select lines.

8. The method of claim 7, wherein forming a second memory cell array, a page buffer, and decoders over the second substrate comprises:
forming second drain select lines, second source select lines, and second word lines disposed between the second drain select lines and the second source select lines over the second substrate; and
forming a second junction in the second substrate between the second drain select lines.

9. The method of claim 8, wherein the coupling structure comprises:
a first contact plug coupled to the first and second junctions;
a second contact plug coupled to the page buffer; and
a bit line coupled to the first and second contact plugs.

10. The method of claim 8, wherein the decoders comprise:
a first decoder operated in conjunction with the first memory cell array; and
a second decoder operated in conjunction with the second memory cell array.

11. The method of claim 10, wherein the coupling structure comprises:
a third contact plug coupled to the first word line;
a fourth contact plug coupled to the second word line;
a fifth contact plug coupled to the first decoder;
a sixth contact plug coupled to the second decoder;
a first signal line coupled to the third and fifth contact plugs; and
a second signal line coupled to the fourth and sixth contact plugs.

12. The method of claim 10, wherein the first and second decoders face each other with the second memory cell array interposed between the first and second decoders.

13. The method of claim 6, further comprising implanting hydrogen ions into the second substrate, before adhering the second substrate.

14. The method of claim 13, further comprising removing part of the second substrate to a depth where the hydrogen ions have been implanted so that the second substrate is made thin, before forming the second memory cell array, the page buffer, and the decoders.
